(19) United States
(12) Patent Application Publication
(10) Pub. No.: US 2005/0135638 A1
(43) Pub. Date: Jun. 23, 2005

(54) Sound output method and apparatus

(76) Inventor: Indy Chu, Chung Ho City (TW)

Correspondence Address: Indy Chu, PO Box 82-144, Taipei, TW

(21) Appl. No.: 10/737,771

(22) Filed: Dec. 18, 2003

(51) Int. Cl. H04B 15/00; H03G 3/00

(52) U.S. Cl. 381/94.5; 381/104

(57) ABSTRACT

A sound output device and apparatus is disclosed. The apparatus provides limitation of sound output, wherein when sound is output to mute or disabling mute, excessive volume of sound output will not occur and therefore the human ear is protected.

### BACKGROUND OF THE INVENTION

(a) Technical Field of the Invention

The present invention relates to a method of sound output and an apparatus of sound output, and in particular, an apparatus that does not generate excessive loudness when switching from mute to sound output.

(b) Brief Description of The Prior Art

FIG. 1 shows sectional view of a human ear. FIG. 2 is a schematic view showing a conventional sound output device. As shown in FIG. 2, from (1-a) sound source voltage adjustment point to (2) sound source voltage adjustment point or from point (3) to point (1-6) is the mode of adjustment of the user with respect to sound. If mute is required, point (4-a) to (4-b), the volume is an appropriate volume acceptable to the user, i.e., from point (5-a) to point (5-b), there is no damage to the audiotary or nerves. Even though from point (6) to point (7), the volume is increased greatly, the need of the user is an increase in the form of a curve. However, from point (8-a) to (8-b), and from (8-b) to (9-a), the user has adapted to the O dh sound output. From point (9-a) to (9-b) where mute is disenabled, the sudden increase of sound volume will seriously damage the audiotary and nerves. Therefore, it is a main object of the present invention to limit the output of sound.

### SUMMARY OF THE INVENTION

Accordingly, it is an object of the present invention to provide an apparatus for sound output with limitation comprises an input unit having a signal connector for input of input signal; a filter unit for filtering input signal which is interfered by external noise and connected to a rear amplification circuit; an amplification unit which amplifies signals from input unit via the filter unit to the output device and to provide a control input end for controlling of output signal; a CPU having an input end and an output end and the input end providing open or close signals input and the output end providing analog signal for controlling the input end of the amplification unit; and an output unit connecting the amplification unit to output signal and convert the signal to sound frequency signal.

Yet another object of the present invention to provide a sound output method and apparatus, wherein the input end of the CPU is MUTE key or volume increase and volume decrease key being pressed together.

Still another object of the present invention is to provide a method of sound output comprising the steps of pressing MUTE key or press the volume increase and volume decrease key together to provide mute; pressing once again the MUTE key or the volume increase and volume decrease key together or pressing alone the volume increase key or volume decrease key, the volume output being added to the output volume before MUTE.

Yet still a further object of the present invention is to provide a sound output method and apparatus, wherein the sound output is environment noise basic value.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view of a human ear.

FIG. 2 is a schematic view of a conventional sound output device.

FIG. 3A is a schematic view of a sound output device in accordance with the present invention.

FIG. 3B is a schematic view showing another output device in accordance with the present invention.

FIG. 4 is a schematic view of a sound output device of the present invention.

FIG. 5 is a schematic view of another sound output device of the present invention.

FIG. 6 is a schematic view showing the relationship between the sound output limit and CPU input section in accordance with the present invention.

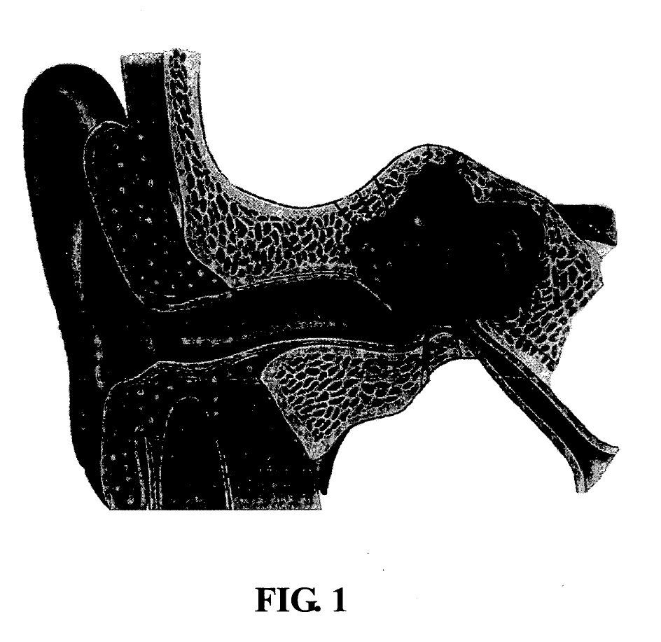

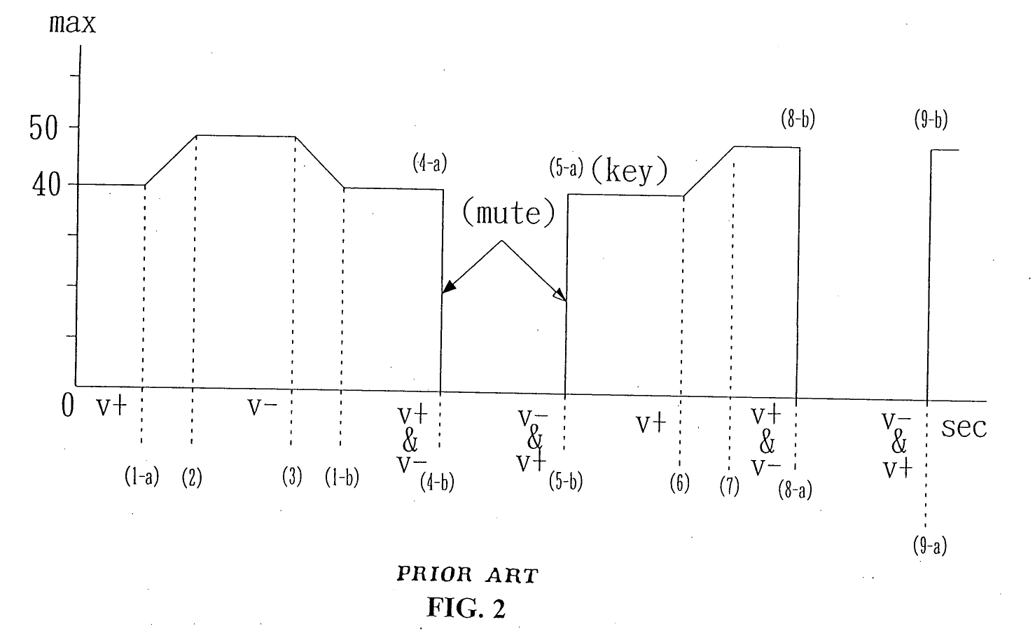

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

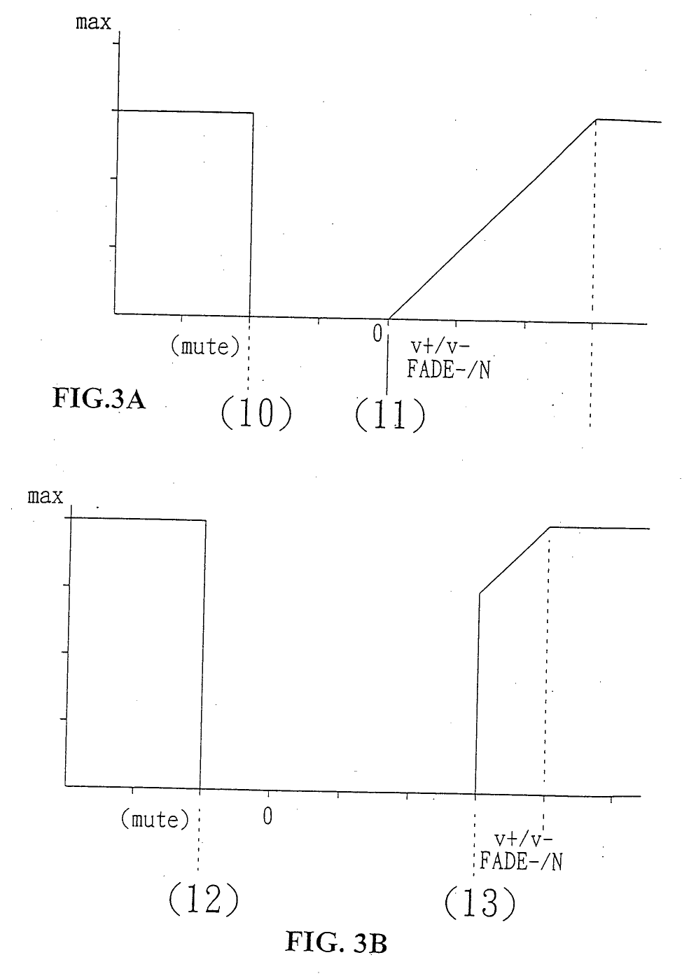

Referring to FIG. 3A, there is shown a method and an apparatus of sound output. Reference number 10 denotes sound source voltage adjustment point. When MUTE is executed and is to be released, the initial value after releasing is from O voltage and is an inclination angle with X-axis and is linear gradually increase to the level of sound source voltage adjustment point before mute. Thus, the user under a quiet environment will not experience a loud sound rapidly after the MUTE key is released or disabled.

When noise level has reached a level, the user may feel whether the sound output is normal. Thus, as shown at point 12 of FIG. 3B, when the mute is going to be released, the initial value from environmental noise basic value voltage will first form a perpendicular inclined with X-axis and then an inclined with X-axis to point 13. Thus even the environment's noise has a constant value, the user can discover the sound source.

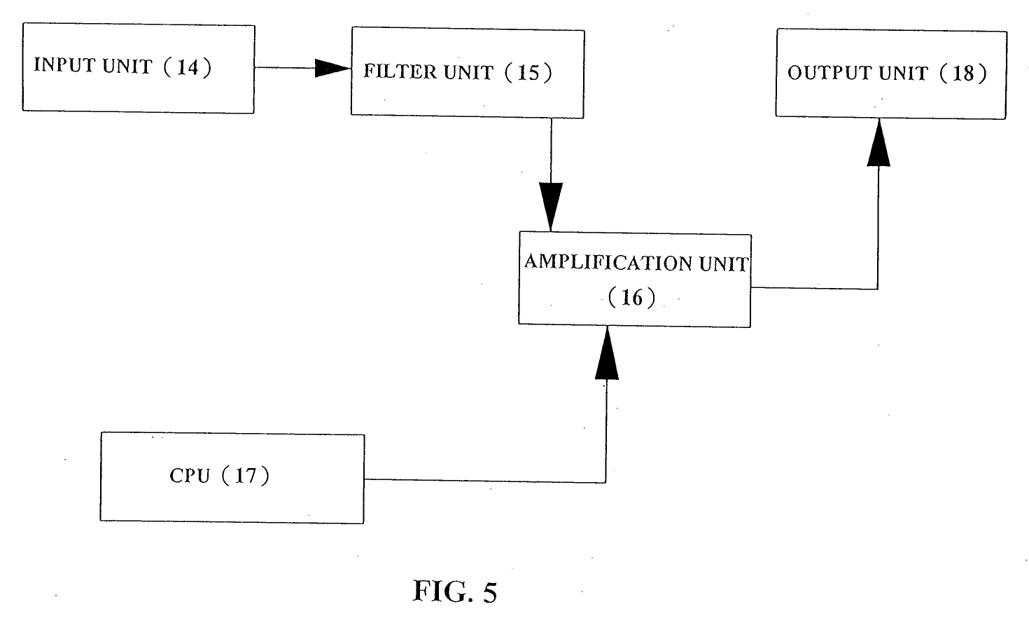

As shown in FIG. 5, the present invention of an apparatus for sound output with limitation comprises an input unit having a signal connector for input of input signal; a filter unit for filtering input signal which is interfered by external noise and connected to a rear amplification circuit; an amplification unit which amplifies signals from input unit via the filter unit to the output device and to provide a control input end for controlling of output signal; a CPU having an input end and an output end and the input end providing open or close signals input and the output end providing analog signal for controlling the input end of the amplification unit; and an output unit connecting the amplification unit to output signal and convert the signal to sound frequency signal.

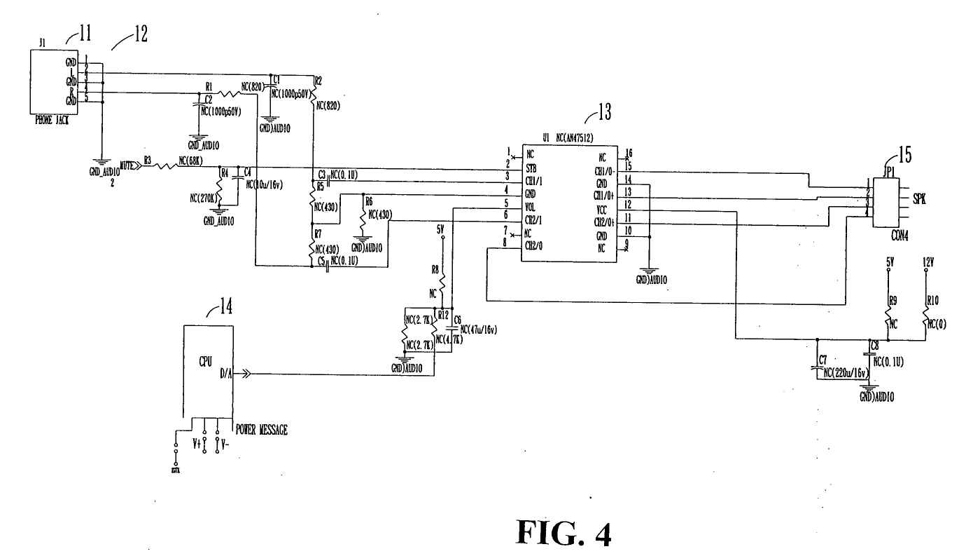

As shown in FIG. 4, when signal from the input unit 14 passes through the filter unit 15 to the amplification unit 16 and then to the output unit 18, the CPU 17 will control the sound voltage of the amplification unit 16. The CPU 17 has input portions like that of mute control, sound level increasing or decreasing. Thus, the device of the present invention attains the sound output method and the sound output can be limited or restricted.

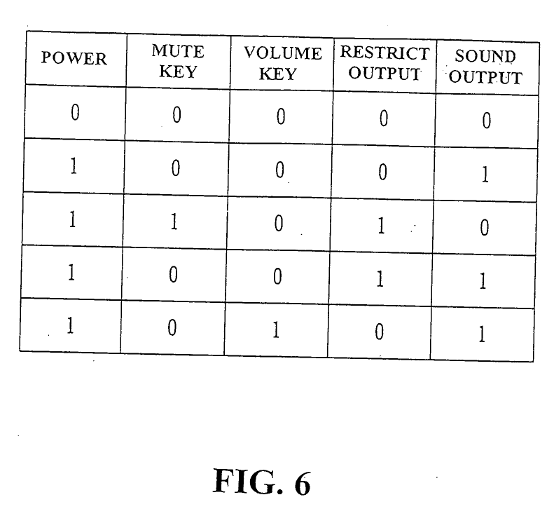

Referring to FIG. 6, there is shown the input portion of the CPU 17. This is used to show the damage of transistors, transformer or rectifier by surge and it is important to restrict or limit sound output.

The advantages of the present invention are that
(1) The device according to the present invention can protect human audiotary. The sound output after the MUTE key is being released is kept at a limited level. This level will not affect or damage ear membrane.
(2) The device prevents sudden shock to human as a result of sudden increase of sound level.
(3) The hardware of the circuit will not be damaged by the increase of sound level, which generates surge voltage and current.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. An apparatus for sound output with limitation comprises:
(1) an input unit having a signal connector for input of input signal;
(2) a filter unit for filtering input signal which is interfered by external noise and connected to a rear amplification circuit;
(3) an amplification unit which amplifies signals from input unit via the filter unit to the output device and to provide a control input end for controlling of output signal;
(4) a CPU having an input end and an output end and the input end providing open or close signals input and the output end providing analog signal for controlling the input end of the amplification unit; and
(5) an output unit connecting the amplification unit to output signal and convert the signal to sound frequency signal.

2. The apparatus for sound output with limitation of claim 1, wherein the input end of the CPU is MUTE key or volume increase and volume decrease key being pressed together.

3. A method of sound output comprising the steps of:
(1) pressing MUTE key or press the volume increase and volume decrease key together to provide mute;
(2) pressing once again the MUTE key or the volume increase and volume decrease key together or pressing alone the volume increase key or volume decrease key, the volume output being added to the output volume before MUTE.

4. The method of claim 1, wherein the sound output is environment noise basic value.

5. The method of claim 1, wherein the filter unit is RC circuit.

6. The method of claim 1, wherein the amplification unit is a packed IC of a rear amplification circuit.

7. The method of claim 1, wherein the CPU is an algorithm circuit, which can output the result as analog signals.

8. The method of claim 1, wherein the output unit is a loudspeaker.
